(19) United States
(12) Patent Application Publication
(10) Pub. No.: US 2006/0278375 A1
(43) Pub. Date: Dec. 14, 2006

(54) Heat sink apparatus with operating fluid in base thereof

(75) Inventor: Hsin-Ho Lee, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/450,478

(22) Filed: Jun. 9, 2006

(30) Foreign Application Priority Data
Jun. 10, 2005 (CN) 200510035288.7

(51) Int. Cl. H05K 7/20

(52) U.S. Cl. 165/104.33; 361/697; 361/700

(57) ABSTRACT

An exemplary heat sink apparatus (10) includes a base (12) and a number of fins (14) extending from an upper external first surface (124) of the base. The base defines a sealed cavity (122) therein. Operating fluid (18) is filled in the cavity. The operating fluid is liquid form. In use, heat produced by a heat source is transferred to the base. Then, the liquid operating fluid in the base absorbs the heat and is vaporized. The vaporized operating fluid is diffused to an upper inner wall (126) of the base and releases the heat, thereby being transformed back into liquid form. The fins transfer the heat to the ambient environment. The heat sink apparatus can dissipate the heat produced by the heat source to the ambient environment quickly and uniformly by adopting the operating fluid. Thus, the thermal operating efficiency and effect of the heat sink apparatus are enhanced.

### BACKGROUND

1. Field of the Invention

The invention relates generally to thermal transmitting structures, and more particularly to a heat sink apparatus utilizing operating fluid and thereby having enhanced heat dissipating efficiency.

2. Related Art

Electronic components, such as semiconductor chips, are becoming progressively smaller with each new product release, while at the same time the heat dissipation requirements of these kinds of components are increasing due to their improved ability to provide more functionality. In many contemporary applications, a heat sink apparatus is one of the most efficient systems in use for transmitting heat away from such components.

Generally, a typical heat sink apparatus includes a base portion, and a predetermined number of parallel fins projecting from an upper section of the base portion. The fins project a predetermined distance or height, and at a predetermined angle, from the upper section. The heat sink apparatus is usually constructed of metals such as aluminum, aluminum alloy, copper, and copper alloy. The base portion includes a base surface. In typical use, the base surface is positioned against a heat transfer surface of an electronic device package, and is firmly held in contact with the heat transfer surface in order to ensure good thermal transfer between the two surfaces.

The metals including aluminum, aluminum alloy, copper, and copper alloy all have relatively high coefficients of thermal conduction. Thus the heat sink apparatus can readily absorb heat produced by electronic devices contained in the electronic device package, and dissipate such heat to the ambient environment. However, many modern electronic device packages are very compact and generate much heat, and in some cases the above-described heat sink apparatus may not be able to transfer the heat from the electronic device package to the ambient environment quickly enough. This is apt to produce hotspots in the heat sink apparatus, and usually results in nonuniform dissipation of heat from the heat sink apparatus. That is, the thermal operating efficiency of the heat sink apparatus may be unsatisfactory.

What is needed, therefore, is a heat sink apparatus having enhanced heat dissipating efficiency.

### SUMMARY

In one embodiment, a heat sink apparatus includes a base and a plurality of fins extending from one surface of the base. The base defines a hermetically sealed cavity defined therein. Operating fluid is filled in the cavity. The operating fluid is liquid form. In use, heat produced by a heat source is transferred to the base. Then, the liquid operating fluid in the base absorbs the heat and is vaporized. The vaporized operating fluid is diffused to an upper inner wall of the base and releases the heat, thereby being transformed back into liquid form. The fins transfer the heat to the ambient environment.

Other advantages and novel features of the present heat sink apparatus will become more apparent from the following detailed description of preferred embodiments when taken in conjunction with the accompanying drawings.

### BRIEF DESCRIPTION OF THE DRAWINGS

The components in the drawings are not necessarily to scale, the emphasis instead being placed upon clearly illustrating the principles of the present heat sink apparatus. Moreover, in the drawings, all the views are schematic, and like reference numerals designate corresponding parts throughout the several views.

FIG. 1 is a cross-sectional view of a heat sink apparatus in accordance with a first exemplary embodiment of the present invention.

FIG. 2 is a cross-sectional view of a heat sink apparatus in accordance with a second exemplary embodiment of the present invention.

FIG. 3 is a cross-sectional view of a heat sink apparatus in accordance with a third exemplary embodiment of the present invention.

The exemplifications set out herein illustrate at least one preferred embodiment of the present heat sink apparatus, in one form, and such exemplifications are not to be construed as limiting the scope of the invention in any manner.

### DETAILED DESCRIPTION OF PREFERRED EMBODIMENTS

Reference will now be made to the drawings to describe embodiments of the present heat sink apparatus in detail.

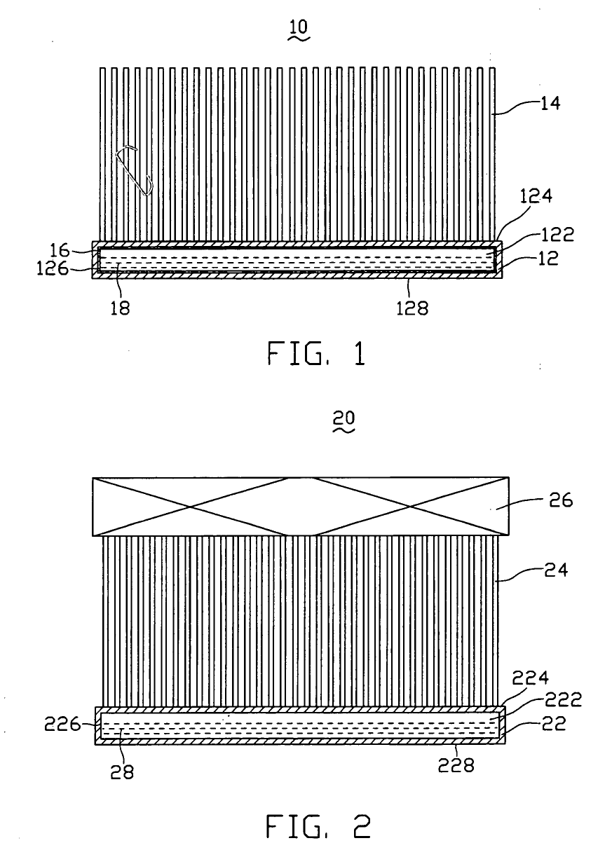

Referring to FIG. 1, a heat sink apparatus 10 in accordance with a first exemplary embodiment of the present invention includes a base 12, a plurality of fins 14, and operating fluid 18. The base 12 has an upper external first surface 124 and a lower external second surface 128. The base 12 defines a hermetically sealed cavity 122 therein, which is surrounded by a plurality of inner walls 126. The inner walls 126 include an upper inner wall 126, a lower inner wall 126, and four side inner walls 126; however, only one of the side inner walls 126 is labeled in FIG. 1. The upper inner wall 126 is nearest to the first surface 124, and is opposite to the lower inner wall 126. The side inner walls 126 interconnect the upper and lower inner walls 126. The fins 14 are substantially parallel to each other, and extend from the first surface 124 of the base 12. In the art, the operating fluid 18 is also commonly known as working fluid. The operating fluid 18 is filled in the sealed cavity 122 of the base 12. When the heat sink apparatus 10 is not in use, the operating fluid 18 is in liquid form, and is supported on the lower inner wall 126. Preferably, a protection layer 16 is coated on the inner walls 126.

The base 12 is preferably made of material selected from the group consisting of copper, aluminum, stainless steel, and any suitable alloy thereof. The base 12 can be formed by welding a pair of metal plates together. Each metal plate has a peripheral flange. The metal plates are welded together at the flanges, thereby forming the base 12 having the cavity 122 therein. Then the cavity 122 is vacuumized, and the operating fluid 18 filled in the cavity 122. Finally, the cavity 122 is sealed. A volume of the operating fluid 18 is in the range of approximately ten percent to approximately ninety percent of a volume of the cavity 122. The operating fluid 18 is preferably selected from the group consisting of water, ammonia, methanol, ethanol, hexanol, acetone, and heptane. Furthermore, the operating fluid 18 preferably has heat conduction materials (not shown) added therein. The heat conduction materials are preferably selected from the group consisting of copper powder, carbon nanotubes, carbon nanospheres, and carbon nanofibers.

The fins 14 are preferably made of a material selected from the group consisting of copper, aluminum, stainless steel, and any suitable alloy thereof. The fins 14 can be integrally molded with the base 12. Alternatively, the fins 14 can be attached on the first surface 124 of the base 12 by means of welding.

The protection layer 126 has stable chemical and physical properties that are compatible with the operating fluid 18. That is, no reaction occurs between the protection layer 16 and the operating fluid 18. In particular, the protection layer 16 is made of material with a high coefficient of thermal conduction, such as graphite, diamond-like carbon material, or nano-scaled carbon material. Preferably, the protection layer 16 is made of nano-scaled carbon material selected from the group consisting of carbon nanotubes, carbon nanospheres, and carbon nanofibers.

In typical use, the second surface 128 of the base 12 engages with an electronic device (not shown). Heat produced by the electronic device is transferred to the operating fluid 18 by conduction through the base 12, and the temperature of the operating fluid 18 rises. When the temperature of the operating fluid 18 reaches and passes a vaporization/boiling temperature of the operating fluid 18, the operating fluid 18 becomes vaporized. Vapor pressure drives the vaporized operating fluid 18 to the upper inner wall 126 of the base 12. At the upper inner wall 126, the vaporized operating fluid 18 transmits the heat to the fins 14 by conduction through the base 12, and the vaporized operating fluid 18 is thereby transformed back into liquid form. The fins 14 dissipate the heat to the external environment. Gravity drives the operating fluid 18 back to the lower inner wall 126. The heat sink apparatus 10 continues this cyclical process of transmitting heat as long as there is a temperature differential between the heat sink apparatus 10 and the electronic device, and as long as the heat is sufficient to vaporize the operating fluid 18.

Compared with a conventional heat sink apparatus, the present heat sink apparatus 10 with the operating fluid 18 can quickly dissipate the heat produced by the electronic device to the ambient environment. Thus, development of hotspots in the heat sink apparatus 10 can be avoided. This helps ensure that the heat sink apparatus 10 dissipates heat uniformly. Therefore, the thermal operating efficiency of the heat sink apparatus 10 is most apt to be satisfactory.

Referring to FIG. 2, a heat sink apparatus 20 in accordance with a second exemplary embodiment of the present invention includes a base 22, a plurality of fins 24, operating fluid 28, and a fan 26. The base 22 has an upper external first surface 224 and a lower external second surface 228. The base 22 defines a hermetically sealed cavity 222 therein, which is surrounded by a plurality of inner walls 226. The inner walls 226 include an upper inner wall 226, a lower inner wall 226, and four side inner walls 226; however, only one of the side inner walls 226 is labeled in FIG. 2. The upper inner wall 226 is nearest to the first surface 224, and is opposite to the lower inner wall 226. The side inner walls 226 interconnect the upper and lower inner walls 226. The fins 24 are substantially parallel to each other, and extend from the first surface 224 of the base 22. The operating fluid 28 is filled in the sealed cavity 222 of the base 22. When the heat sink apparatus 20 is not in use, the operating fluid 28 is in liquid form, and is supported on the lower inner wall 226. Preferably, a protection layer (not shown) is coated on the inner walls 226. The fan 26 is attached on free ends of the fins 24, by any of a variety of means as would be known to those of ordinary skill in the art. For example, the fan 26 and the free ends of the fins 24 can be provided with complementary interengaging means. Such complementary interengaging means can for example include resiliently deformable clip portions provided on the fan 26, and engaging slots provided in selected of the free ends of the fins 24.

As seen, the heat sink apparatus 20 is similar to the above-described heat sink apparatus 10, except that the heat sink apparatus 20 further includes the fan 26 located on the free ends of the fins 24. In use, the fan 26 can accelerate convection of ambient air near the fins 24. This can further accelerate dissipation of heat from the fins 24. Thus, the thermal operating efficiency of the heat sink apparatus 20 is further enhanced.

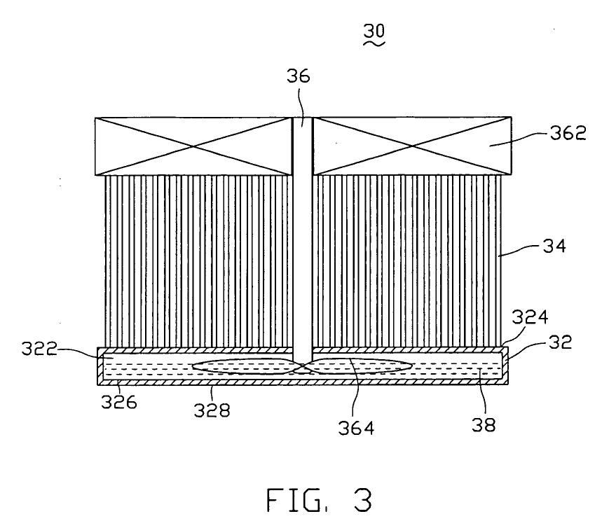

Referring to FIG. 3, a heat sink apparatus 30 in accordance with a third exemplary embodiment of the present invention includes a base 32, a plurality of fins 34, operating fluid 38, a first fan 362, and a second fan 364. The base 32 has an upper external first surface 324 and a lower external second surface 328. The base 32 defines a hermetically sealed cavity 322 therein, which is surrounded by a plurality of inner walls 326. The inner walls 326 include an upper inner wall 326, a lower inner wall 326, and four side inner walls 326; however, only the lower inner wall 326 is labeled in FIG. 3. The upper inner wall 326 is nearest to the first surface 324, and is opposite to the lower inner wall 326. The side inner walls 326 interconnect the upper and lower inner walls 326. The fins 34 are substantially parallel to each other, and extend from the first surface 324 of the base 32. The operating fluid 38 is filled in the sealed cavity 322 of the base 32. When the heat sink apparatus 30 is not in use, the operating fluid 38 is in liquid form, and is supported on the lower inner wall 326. Preferably, a protection layer (not shown) is coated on the inner walls 326. The first fan 362 is located on free ends of the fins 34. The second fan 364 is substantially located in the cavity 322. The first and second fans 362, 364 commonly use a single axle 36. That is, the axle 36 extends through the base 32 into the cavity 322. A sealing material (not shown) is provided between the axle 36 and the base 32, in order to ensure that the cavity 322 is sealed. The sealing material can be lubricating oil. In use, the axle 36 can rotate smoothly, thereby driving the first and second fans 362, 364 to rotate correspondingly.

As seen, the heat sink apparatus 30 is similar to the above-described heat sink apparatus 20, except that the heat sink apparatus 30 further includes the second fan 364 located in the cavity 322. In use, the second fan 364 can accelerate diffusion of vaporized operating fluid 38 and flowing of liquid operating fluid 38. This can further accelerate eventual dissipation of heat from the fins 34. Thus, the thermal operating efficiency of the heat sink apparatus 30 is further enhanced.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

I claim:

1. A heat sink apparatus comprising:
a base defining a hermetically sealed cavity therein and including one external surface;
a plurality of fins extending from the external surface of the base; and
operating fluid filled in the sealed cavity of the base.

2. The heat sink apparatus as claimed in claim 1, wherein the base is made of a material selected from the group consisting of copper, aluminum, and stainless steel.

3. The heat sink apparatus as claimed in claim 1, wherein the fins are made of a material selected from the group consisting of copper, aluminum, and stainless steel.

4. The heat sink apparatus as claimed in claim 1, wherein the base further includes inner walls surrounding the cavity.

5. The heat sink apparatus as claimed in claim 4, wherein the base further includes a protection layer coated on the inner walls.

6. The heat sink apparatus as claimed in claim 5, wherein the protection layer is made of carbon materials.

7. The heat sink apparatus as claimed in claim 6, wherein the carbon materials are selected from the group consisting of graphite, diamond-like carbon material, and nano-scaled carbon material.

8. The heat sink apparatus as claimed in claim 7, wherein the nano-scaled carbon material is selected from the group consisting of carbon nanotubes, carbon nanospheres, and carbon nanofibers.

9. The heat sink apparatus as claimed in claim 1, wherein the operating fluid is selected from the group consisting of water, ammonia, methanol, ethanol, hexanol, acetone, and heptane.

10. The heat sink apparatus as claimed in claim 1, wherein a volume of the operating fluid is in the range of approximately ten percent to approximately ninety percent of a volume of the cavity.

11. The heat sink apparatus as claimed in claim 1, wherein the operating fluid has heat conduction materials added therein.

12. The heat sink apparatus as claimed in claim 11, wherein the heat conduction materials are selected from the group consisting of copper powder, carbon nanotubes, carbon nanospheres, and carbon nanofibers.

13. The heat sink apparatus as claimed in claim 1, further comprising a first fan attached on free ends of the fins.

14. The heat sink apparatus as claimed in claim 13, further comprising a second fan substantially located in the cavity of the base, wherein the first and second fans commonly include a shared single axle.

15. The heat sink apparatus as claimed in claim 14, wherein a sealing material is provided between the axle and the base to ensure that the cavity is sealed.

16. The heat sink apparatus as claimed in claim 15, wherein the sealing material is lubricating oil.
